(19) United States
(12) Patent Application Publication
(10) Pub. No.: US 2019/0115488 A1
(43) Pub. Date: Apr. 18, 2019

(54) Multilayer photoreceptor device, layers of which have different lattice parameters

(71) Applicants: Centre national de la recherche scientifique, PARIS (FR); Sorbonne Université, PARIS (FR); CENTRALESUPELEC, GIF SUR YVETTE (FR)

(72) Inventors: Denis MENCARAGLIA, BURES SUR YVETTE (FR); Daniel BOUCHIER, LES ULIS (FR); Charles RENARD, MAGNY LES HAMEAUX (FR); James CONNOLY, LE BARROUX (FR); Thimothée MOLIERE, VALENTON (FR)

(73) Assignees: Centre national de la recherche scientifique, PARIS (FR); Sorbonne Université, PARIS (FR); CENTRALESUPELEC, GIF SUR YVETTE (FR)

(21) Appl. No.: 16/094,657

(22) PCT Filed: Apr. 18, 2017
(86) PCT No.: PCT/EP2017/059146

§ 371 Date: Oct. 18, 2018

(30) Foreign Application Priority Data
Apr. 18, 2016 (FR) 16 53419

(51) Int. Cl. H01L 31/18; H01L 31/036; H01L 31/0304; H01L 31/0687; H01L 31/0216

(52) U.S. Cl. CPC H01L 31/18; H01L 31/036; H01L 31/02167; H01L 31/0687; H01L 31/0304

(57) ABSTRACT

The invention relates to a photoreceptor device, with a first crystalline, semi-conductive material, comprising a first lattice parameter, and a second crystalline, semi-conductive material, deposited on the first material and comprising a second lattice parameter, different from the first lattice parameter. In particular, the device comprises an interface layer between the first and second materials, made from an amorphous material and structured to comprise regularly spaced apart openings in the plane of the layer. The second material comprises protuberances coming out of the openings of the interface layer and forming separated crystal grains, each grain comprising a plurality of facets forming at least one angle relative to one another.

The present invention relates to the field of photoreceptor devices, in particular for photovoltaic applications, and the thin layer manufacturing methods of such devices.

Here, “photoreceptor device” refers to any electronic device capable of converting a reception of light either into electrical energy, such as photovoltaic devices, or into an electrical signal, such as photoresistors.

By way of non-limiting example, at least two materials can be involved in manufacturing such a device. For example, this involves:

a substrate of a first material, with a base of silicon (hereinafter Si), and

a thin layer with a base of gallium arsenide (hereinafter GaAs), or a ternary alloy comprising aluminum in addition to this binary material (AlGaAs), deposited on the silicon substrate.

Using these two types of materials, one deposited on the other, may have an advantage in the photovoltaic field, in particular in the design of so-called “tandem” cells, due to their respective band gaps (or “gap” hereinafter), offering an efficiency close to the expected theoretical maximum in terms of photovoltaic conversion.

However, one difficulty in depositing one such material on the other lies in the fact that their respective crystallographic structures have different lattice parameters (different inter-atomic distances of the Si material, with respect to the other GaAs).

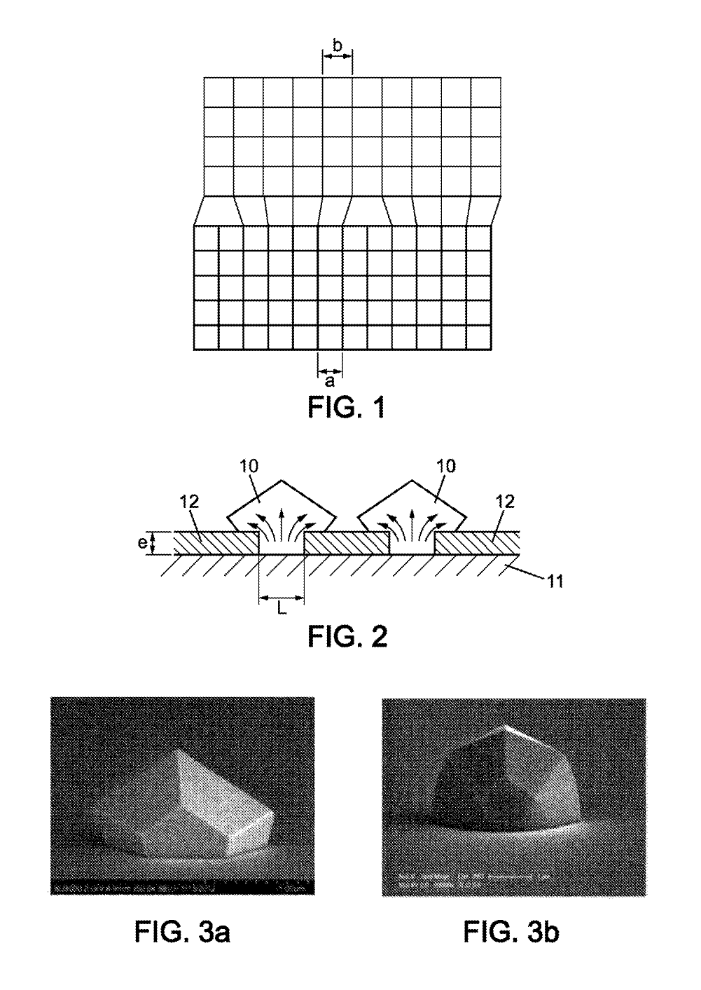

In reference to FIG. 1, it in fact appears that when the lattice parameters are different (respectively a for Si and b for GaAs), stresses, then dislocations (beyond a critical height of deposited material) may appear due to the poor interatomic alignment between the two materials. This results in electrically active faults that may degrade the performance of the device.

Furthermore, it is interesting for the surface of the thin layer (intended to receive light) to be textured in order to trap the light, and thus to increase the photon-material interaction surfaces of the photoreceptor device. Currently, texturing the surface of a thin layer after growth thereof is delicate and time-consuming to do in order to obtain suboptimal remaining performance levels.

The present invention improves this situation.

To that end, it proposes a photoreceptor device, comprising at least:

a first crystalline, semi-conductive material, comprising a first lattice parameter, and

a second crystalline, semi-conductive material, deposited on the first material and comprising a second lattice parameter, different from the first lattice parameter.

In particular:

the device comprises an interface layer between the first and second materials, made from an amorphous material and structured to comprise regularly spaced apart openings in the plane of the layer,

the second material comprises protuberances coming out of the openings of the interface layer and forming separated crystal grains, each grain comprising a plurality of facets forming at least one angle relative to one another.

Owing to this arrangement, the openings formed in the amorphous layer make it possible to accompany the growth of the second material, initially constrained, then relaxing without dislocation, to form crystalline grains comprising multiple facets to trap the light effectively.

Thus, the method according to the invention makes it possible to obtain natural texturing of the thin layer of the second material during its growth, without requiring a subsequent additional step.

Furthermore, the interface layer is made from an insulating material (for example an oxide, such as silica deposited on silicon as first material). Nevertheless, the thickness of the interface layer is less than 10 nm (nanometers) to be able advantageously to form a tunnel junction between the first and second materials. With such a small interface layer thickness, the formation of the aforementioned crystalline protuberances has nevertheless been observed, without dislocation.

It will thus be understood that the interface layer can serve both for assistance in the growth of protuberances of the second material, as well as for tunnel effect junction between the first and second materials, which can then be used in a photovoltaic cell of the “tandem” type with one of the first and second materials in the “top” cell and the other material in the “bottom” cell.

An interface layer is known assisting with the growth of such protuberances in the prior art reflected by documents D1: US 2010/236617, D2: EP 2,343,731, D3: WO-2013/154485. Nevertheless, in these documents, the interface layers are not as fine as that within the meaning of the present invention, which further allows a tunnel junction between the two materials. For example, in document D1: US 2010/236617, it is necessary to proceed specifically with the formation of said tunnel effect junction layer in several steps, in particular including a particularly heavy doping step (D1: [0042]). In the context of the present invention, these steps are no longer necessary, particularly advantageously.

The openings of the interface layer may in turn have a width for example between 10 and 100 nm, preferably about 50 nm.

In one embodiment, the first crystalline material preferably has orientation [111], which makes it possible, as will be seen in more detail later, to avoid twinning problems between regions with different crystalline orientations, when the second material is polar (for example such as gallium arsenide).

In one embodiment, the photoconductor device comprises a tandem cell and the first material is used in a first “bottom” cell (bottom cell relative to the incidence of the light), while the second material is used in a second “top” cell.

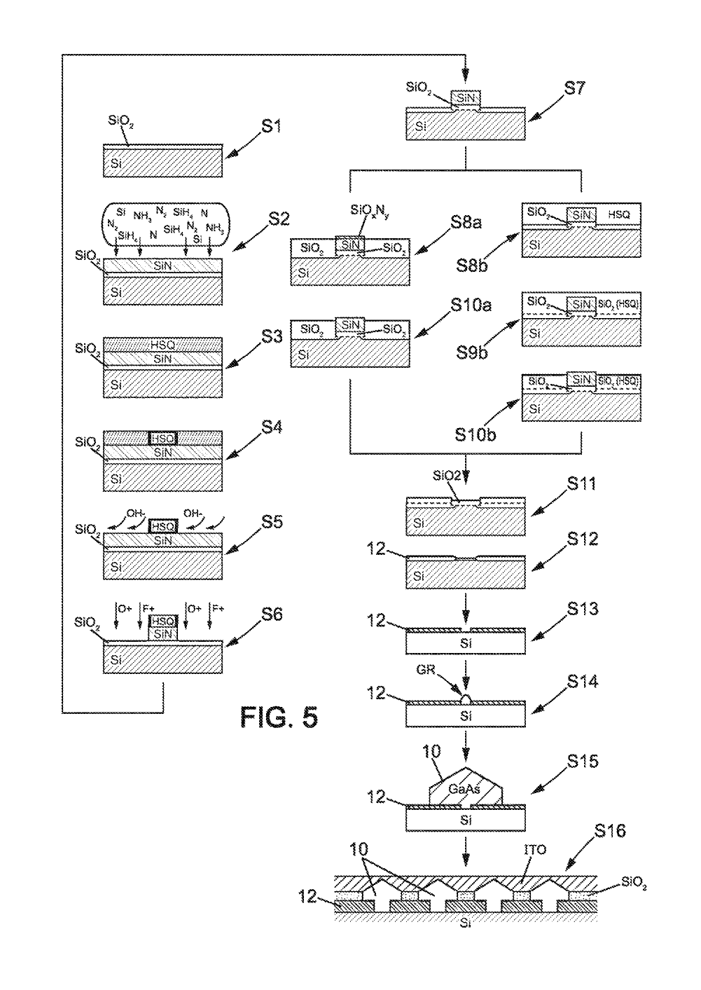

The space between obtained crystalline grains may next be filled in by an insulating layer deposited on the second material (for example, silica SiO₂ as illustrated in reference to step S16 of FIG. 5).

This insulating layer and the grains may next be encapsulated in a conductive and transparent layer (for example ITO as shown in FIG. 5), deposited on the insulating layer (SiO₂).

The present invention also relates to a method for manufacturing a photoreceptor device of the above type, the method in particular comprising at least:

a first step, for forming the aforementioned interface layer, structured to have openings regularly spaced apart and emerging on the first material, and

a second step, for depositing the second material on the first material at least in line with said openings,

the interface layer being made from an insulating material and having a thickness of less than 10 nm (nanometers) to be able advantageously to form a tunnel junction between the first and second materials.

The method may further comprise an intermediate step, between said first and second steps, for depositing a seed of a third material in each of the openings, on which seed the second material is deposited during said second step. This seed may or may not be of the same material as the second material.

The deposition steps are preferably carried out by epitaxy.

The method may comprise a prior step for arranging openings regularly spaced apart in the interface layer, by applying a locally etched mask to form said openings. Such an embodiment will be described in detail in reference to FIG. 5 below.

In particular, said mask is etched partially to leave, at the openings, a thickness of interface layer finer than outside the openings (said thickness being 0.6 nm in one example embodiment described later). This finer layer thickness make it possible to avoid oxidation, in the open air, of the first underlying material. It is then removed before performing the second step or the aforementioned intermediate step.

Other advantages and features of the invention will appear upon reading the following description of example embodiments described below and examining the appended drawings, in which:

FIG. 1 illustrates an example of dislocations related to the growth of one material on the other, in lattice disorder,

FIG. 2 schematically shows the structure allowing a deposition of a thin layer 10 (made up of multiple protuberances), with lattice disorder, on a substrate 11, via a regularly “perforated” interface layer 12,

FIGS. 3a and 3b are transmission electron microscopy images of a gallium arsenide protuberance, deposited on a silicon substrate oriented [001] through a silica interface layer, at a chemical beam epitaxy (CBE) deposition temperature of 575° C. (FIG. 3a) and 550° C. (FIG. 3b),

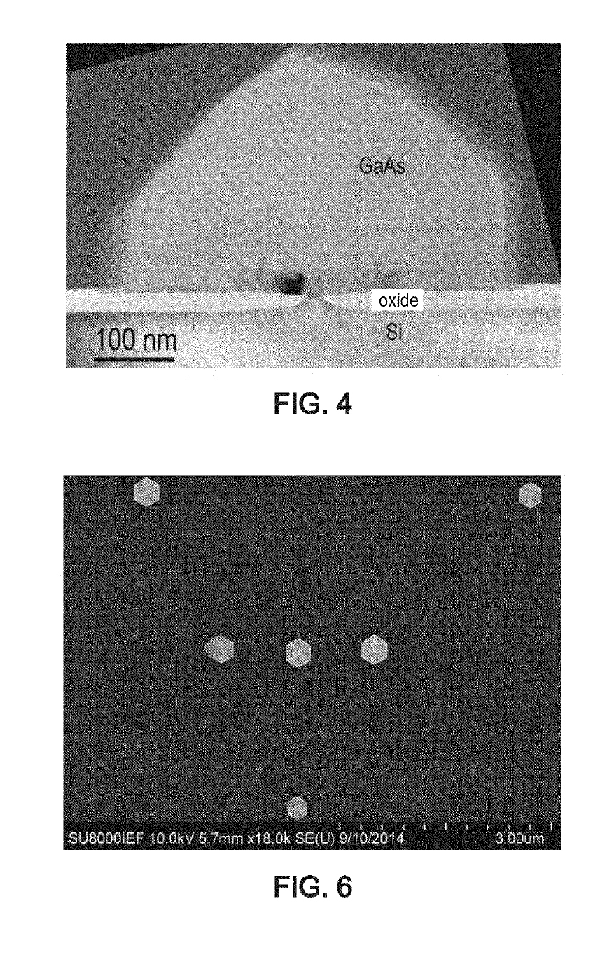

FIG. 4 is a microscopy image showing a protuberance, the interface layer, and the substrate to scale,

FIG. 5 illustrates the different steps of an example method for manufacturing the aforementioned interface layer,

FIG. 6 is a microscopy image showing several regularly spaced apart protuberances, obtained by carrying out the method of FIG. 5, on a [111] crystalline oriented Si substrate.

In reference to FIG. 2, in the described example, gallium arsenide 10 is deposited by epitaxy on a silicon substrate 11 (or on a preparation layer, with a silicon base). However, an interface layer 12 made from oxide (silicon dioxide SiO₂ in the described example) is provided between the substrate 11 and the deposited material 10. The thickness e of the interface layer is less than or about 2 nm (nanometers). This oxide layer 12 is “perforated” in regular locations to allow the substrate 11 to appear bare, in openings with a diameter L of about 20 to 100 nm. The gallium arsenide 10 is deposited progressively on the silicon substrate 11 in the openings left by the interface layer 12. The deposited gallium arsenide is highly stressed, but the stress relaxes gradually over the course of the deposition and the gallium arsenide next forms 3D islands upon leaving the interface layer 12 (arrows in FIG. 2). Thus, by relaxing, the gallium arsenide forms a “mushroom”-shaped protuberance at each opening of the interface layer 12. Each of these protuberances 10 has facets forming angles relative to one another, which depend on the epitaxy temperature (FIGS. 3a and 3b), the crystalline orientation of the substrate, and optionally other parameters.

On the one hand, these protuberances intersect without dislocations. On the other hand, all of these facets effectively trap the light in a photoreceptor device comprising such a global layer 10 (made up of different protuberances) deposited with lattice disorder on the substrate 11. Furthermore, the diameter L of the openings is relatively small (less than 100 nm) relative to the dimensions of the protuberances (of around several microns wide). FIG. 4 illustrates these respective dimensions, to scale. Nevertheless, it has been observed that the carriers could pass by tunnel effect, without difficulty, between the protuberance (GaAs) and the substrate (Si), due to the fineness of the interface layer (oxide) of several nanometers.

Lastly, in the case of gallium arsenide deposited on silicon to manufacture a photovoltaic cell, the respective gaps are such that photovoltaic efficiency records can be achieved.

Nevertheless, in order for the protuberances not to touch one another and thus decrease the efficiency of the trapping of the light, the openings of the interface layer 12 must be arranged regularly in the plane of the layer 12 (by regular intervals along the two axes x,y of the plane of the layer 12, the third axis z being perpendicular to the layer).

We will now refer to FIG. 5 to describe a method, as an example, for preparing regular openings of such an interface layer 12.

The first step S1 consists of preparing the surface of the Si substrate, by chemical cleaning. A fine layer of silica SiO₂ remains. Next, in step S2, silicon nitride SiN is deposited on the layer of silica. In the following step S3, a resin of type HSQ (for Hydrogen silsequioxane) is used to cover the SiN surface with resin.

The following step S4 consists of defining the mask by electronic lithography (definition of a chosen pattern, with regular intervals in both directions x,y of the plane of the HSQ mask. In the following step S5, the resin is “developed” (removed) to leave the nitride SiN on the surface, outside the remaining HSQ polymerized regions. In the following step S6, the mask is transferred, with elimination of the nitride, by Reactive Ion Etching (RIE). Next, a stack more precisely having the shape illustrated relative to step S7 of FIG. 5 is obtained, of localized SiN nitride and silica, on the Si substrate, after post-etching cleaning.

Next, in a first embodiment at a high temperature (1050° C.), it is possible to proceed in step S8a with a dry oxidation, increasing the thickness of the silica layer, followed by step S10a for a deoxidation of the SiN nitride layer. In another embodiment at a lower temperature, it is possible to proceed in step S8b with a thick HSQ resin coating, then a transformation of the HSQ resin into silica in step S9b. Next, by etching in step S10b, in this second embodiment, the remaining nitride studs are extricated.

In steps S11 and S12 (in both embodiments above), it is next possible to perform selective etching of the nitride, then chemical cleaning (Shiraki type, for example) with passivation (using HCl, for example), to ultimately obtain a silica layer smaller than or equal to 2 nm in thickness, on the Si substrate, and in particular, at the future openings, a much finer thickness of silica, of about 0.6 nm (about two atomic planes of silica). This very fine layer of 0.6 nm of silica allows the substrate thus prepared to be placed back in the open air, while avoiding uncontrolled oxidation of the silicon substrate.

Next, in step S13, the substrate bearing the layer of silica can be placed in an epitaxy frame, in which the 0.6 nm of silica is first removed to form the openings, for example by applying thermal flashes (at about 1000° C.) or beforehand by soaking in a hydrofluoric acid (HF) bath. In step S14, in the openings thus freed, one preferably first deposits seeds GR of crystals for nucleation. These seeds can have dimensions of several tens of nanometers. In one example embodiment, this may be gallium arsenide, already (at an epitaxy temperature of 430° C.). Nevertheless, in one alternative, it may be another nucleation material, for example germanium. Typically, germanium (elementary Ge) has good properties for occupying pendant bonds of silicon and concretely covering the entire surface left free of the silicon substrate, at an epitaxy temperature of about 600° C. Thus, using such seeds, it is possible next to finally control the crystalline growth of the seeds (protuberances 10), in particular when the seeds overflow the openings, thus avoiding flaw formation.

After the nucleation step S14, it is next possible to proceed to the growth step S15 by epitaxy of the protuberances forming the crystals 10 (GaAs in the described example), at a temperature between 500° C. and 600° C., and more preferably between 550 and 600° C.

Depending on the epitaxy temperature for example (or depending on the ratio of elements V/III for the GaAs), it is possible to obtain desired facet patterns. However, it has been observed that certain protuberance 10 patterns, and in particular that illustrated in FIG. 3a and obtained at a temperature of 575° C., could have different crystallographic orientations within the meaning of the same crystal grain when the silicon substrate had a traditional [100] crystalline orientation. In the case of regions with different crystalline orientations meeting in an atomic plane, a “twinning” is created in said plane when the material is polar, like gallium arsenide (arsenic As atoms across from arsenic atoms (instead of gallium Ga), and gallium Ga atoms across from gallium atoms (instead of arsenic As)). Such twinnings may deteriorate the mechanical and/or electronic properties of the material.

To overcome this difficulty, it is proposed in one embodiment to deposit the protuberances 10 on a substrate with orientation [111]. The obtained crystal grains 10, as shown in FIG. 6, advantageously do not have any twinning in this embodiment. They have a globally cubic shape, also different from those observed in FIGS. 3a and 3b.

It should further be noted that for a polar material such as gallium arsenide, if the seeds 10 grow more and touch to form a single global GaAs layer, antiphase domains or other flaws may be created, which may make the material electrically defective at the “joints between seeds”.

Once the seeds are obtained, after step S15, it is possible to deposit a layer of silica on the seeds 10 to fill in the spaces between the latter, in a step S16, then a transparent conductive oxide layer (for example indium tin oxide, ITO) to form a collecting layer forming a contact of the photoreceptor device to be manufactured (after any deposition of a passivation layer below the conductive transparent ITO layer). These other steps for completely manufacturing the photoreceptor device, such as a Si—GaAs tandem photovoltaic cell, are not outlined here, the formation of seeds with facets 10 being the particular aim sought in the present invention.

Of course, the present invention is not limited to the embodiments described above; it encompasses other alternatives.

Thus, the method for forming openings in the layer of silica described above in reference to FIG. 5 may be different and allows many alternatives (for example, a deposition of HSQ resin directly forming the final patterns of the SiO₂ layer). In another example, if the constraints in terms of spacing regularity of the openings is relatively low, it is possible initially to provide a single layer of silica, then etching with silane in the epitaxy frame, this etching being light to produce openings spaced apart from one another enough to avoid a risk of subsequent contact of the seeds 10 with one another.

Furthermore, in general, the materials presented as an example above are open to alternatives. For example, germanium may be deposited on silicon (with lattice disorder), or InP on GaAs, or other alternatives. Likewise, the interface layer (of silica above) may be formed in another oxide (titanium or the like). The deposition temperatures, the crystalline substrate orientations, etc., are open to alternatives based on shape, size, orientation, etc., desired for the seeds 10.

1. A photoreceptor device, comprising:
a first crystalline, semi-conductive material, comprising a first lattice parameter, and
a second crystalline, semi-conductive material, deposited on the first material and comprising a second lattice parameter, different from the first lattice parameter, wherein:
the device comprises an interface layer between the first and second materials, made from an amorphous material and structured to comprise regularly spaced apart openings in the plane of the layer,
the second material comprises protuberances coming out of the openings of the interface layer and forming separated crystal grains, each grain comprising a plurality of facets forming at least one angle relative to one another, and
wherein the interface layer is made from an insulating material and having a thickness of less than 10 nm to form a tunnel junction between the first and second materials.

2. The device according to claim 1, wherein the openings of the interface layer have a width between 10 and 100 nm, preferably about 50 nm.

3. The device according to claim 1, wherein the first crystalline material has orientation [111].

4. The device according to claim 1, wherein the second material is polar.

5. The device according to claim 1, wherein the second material is gallium arsenide.

6. The device according to claim 1, wherein the first material is silicon.

7. The device according to claim 1, wherein the device comprises a tandem cell and in that the first material is used in a first bottom cell and the second material is used in a second top cell.

8. The device according to claim 1, wherein spaces between seeds are filled in by an insulating layer, deposited on the second material.

9. The device according to claim 8, wherein the insulating layer and the seeds are encapsulated in a conductive layer, deposited on the insulating layer.

10. A method for manufacturing a device according to claim 1, wherein the method for manufacturing comprises:
a first step, for forming said interface layer, structured to have openings regularly spaced apart and emerging on the first material, and
a second step, for depositing the second material on the first material at least in line with said openings,
wherein the interface layer being made from an insulating material and having a thickness of less than 10 nm to form a tunnel junction between the first and second materials.

11. The method according to claim 10, wherein the method further comprises an intermediate step, between said first and second steps, of depositing a seed of a third material in each of the openings, on which seed the second material is deposited during said second step.

12. The method according to claim 10, wherein said deposition steps are carried out by epitaxy.

13. The method according to claim 10, wherein the method comprises a prior step for arranging openings regularly spaced apart in the interface layer, by applying a locally etched mask to form said openings.

14. The method according to claim 13, wherein said mask is etched partially to leave, at the openings, a thickness of interface layer finer than outside the openings, said finer thickness being removed before performing the second step or said intermediate step.

15. The device according to claim 8, wherein the insulating layer comprises silicon dioxide (SiO2).

16. The device according to claim 9, wherein the conductive layer comprises indium tin oxide (ITO).
